(19) United States
(12) Patent Application Publication
(10) Pub. No.: US 2013/0148274 A1
(43) Pub. Date: Jun. 13, 2013

(54) FASTENING ASSEMBLY OF ELECTRONIC DEVICE

(71) Applicant: YAN-LING GAO, Shenzhen City (CN)

(72) Inventor: YAN-LING GAO, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/459,522

(22) Filed: Apr. 30, 2012

(30) Foreign Application Priority Data
Dec. 9, 2011 (CN) 201110408581.9

(51) Int. Cl. H05K 5/02; F16B 1/00

(52) U.S. Cl. 361/679.01; 24/606

(57) ABSTRACT

A fastening assembly includes a fastening block, a release element, and at least one elastic element. The fastening block includes a sliding groove and a stopper portion defined on the sliding groove. The release element includes a pressing portion defining a rope hole formed therein and a stopper column protruding from the pressing portion towards the stopper portion of the fastening block. The end of the stopper column is releasably locked to the stopper portion. The elastic element resists against the fastening block and the pressing portion. When the pressing portion is pressed towards the fastening block, the end of the stopper column moves and gets around of the stopper portion; when the pressing of the pressing portion is released, the elastic element releases elastic expansion to push the pressing portion away from the fastening block.

### BACKGROUND

1. Technical Field

The present disclosure relates to a fastening assembly and an electronic device using the fastening assembly.

2. Description of Related Art

Electronic devices typically define fastening assemblies allowing external ornaments to be hung from. The fastening assembly may be formed by defining a corner hole in the housing of the electronic device. A cord connecting the ornaments can be hung through the corner hole. However, the hung ornament can be difficult to handle.

Therefore, there is room for improvement within the art.

### BRIEF DESCRIPTION OF THE DRAWINGS

Many aspects of the disclosure can be better understood with reference to the following figures. The components in the figures are not necessarily drawn to scale, the emphasis instead being placed upon clearly illustrating the principles of the disclosure. Moreover, in the drawings, like reference numerals designate corresponding parts throughout the several views.

FIG. 1 is a schematic view of one embodiment of an electronic device.

FIG. 2 is an exploded view of partials of the electronic device shown in FIG. 1.

FIG. 3 is an exploded view of one embodiment of a fastening assembly.

FIG. 4 is another exploded view of the fastening assembly.

FIG. 5 is an isometric view of the fastening assembly shown in FIG. 3 being assembled in a housing of the electronic device shown in FIG. 1.

FIG. 6 is an overhead view of the fastening assembly in a closed status.

FIG. 7 is an overhead view of the fastening assembly in an open status.

### DETAILED DESCRIPTION

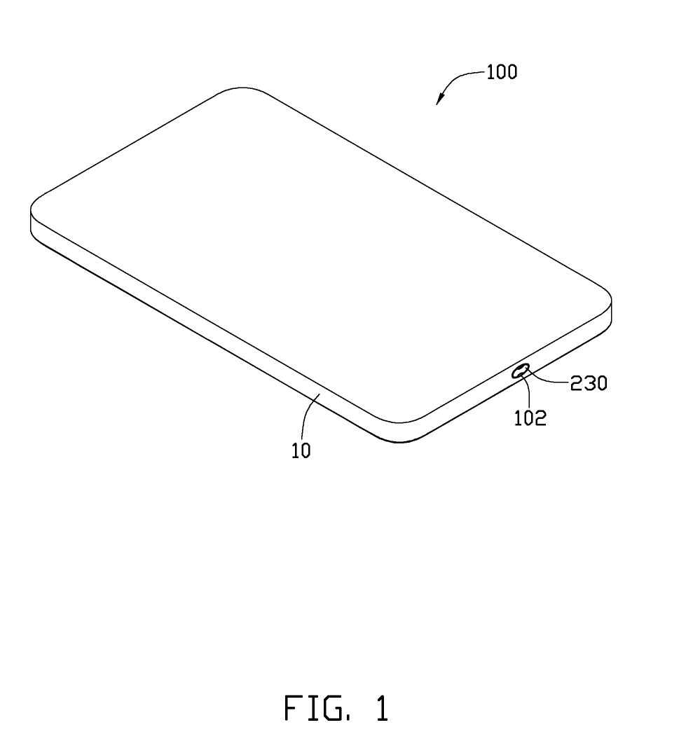

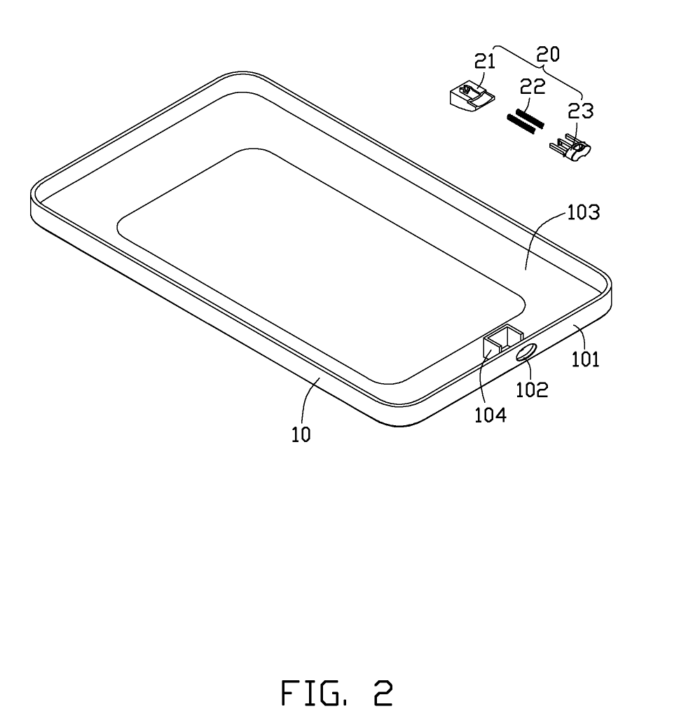

FIG. 1 shows an electronic device 100 according to an exemplary embodiment. The electronic device 100 can be a mobile-phone, a personal digital assistant, or a music player, for example. Also referring to FIG. 2, the electronic device 100 includes a housing 10 and a fastening assembly 20 mounted in the housing 10.

The housing 10 defines a hole 102 in an end wall 101 of the housing 10. The housing 10 defines an inside bottom surface 103. A mounting portion 104 is enclosed by three sidewalls vertically protruding from the inside bottom surface 103, and adjacent to the hole 102.

The fastening assembly 20 includes a fastening block 21, at least one elastic element 22, and a release element 23. In the exemplary embodiment, there are two elastic elements 22.

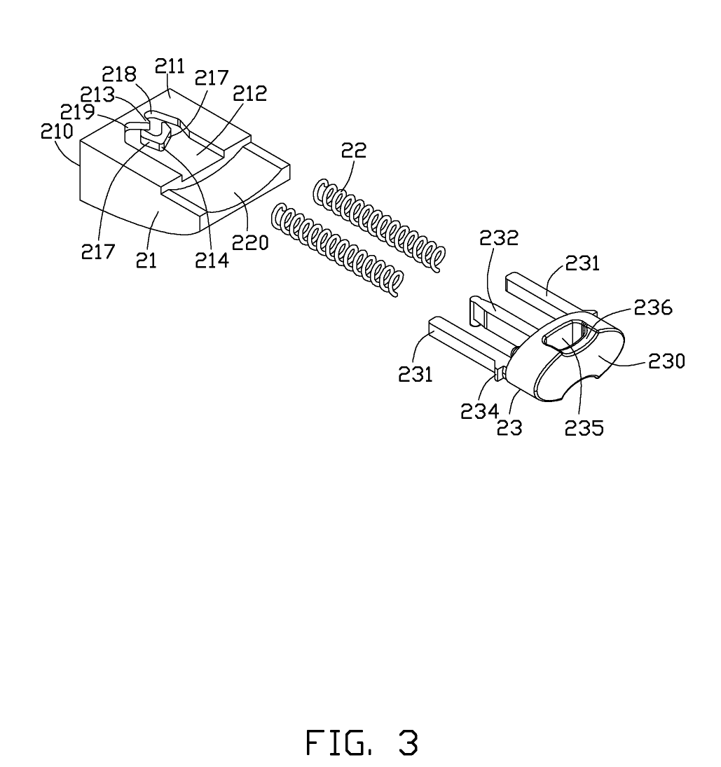

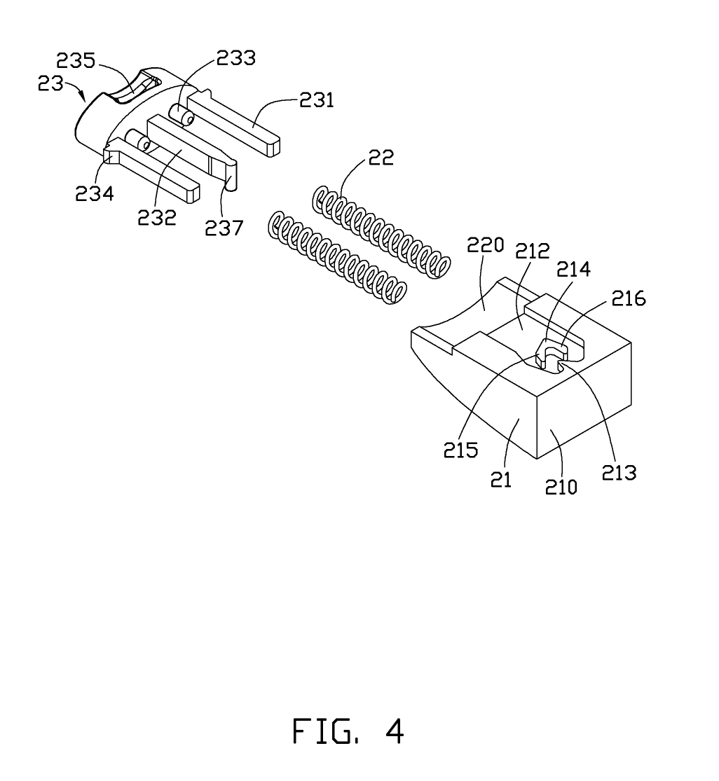

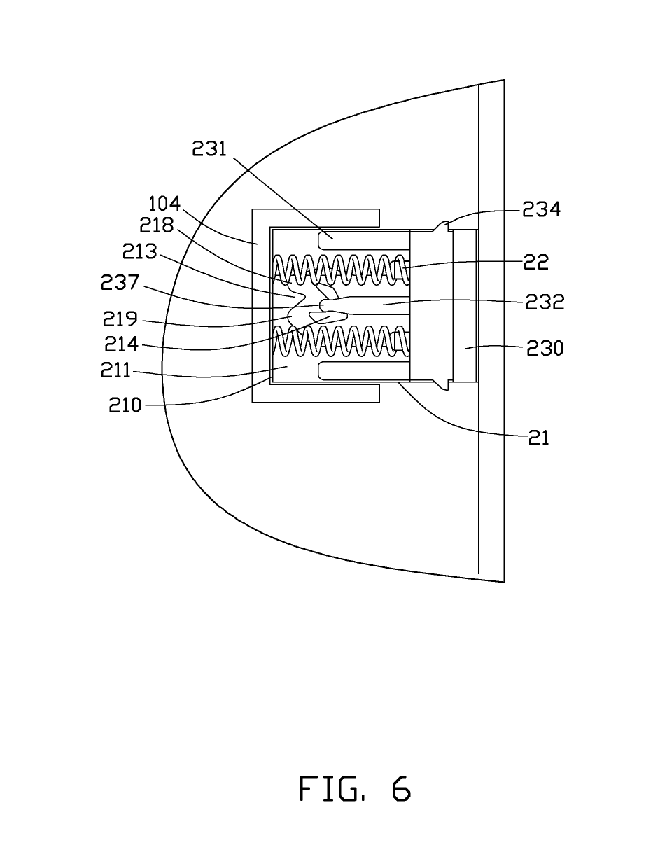

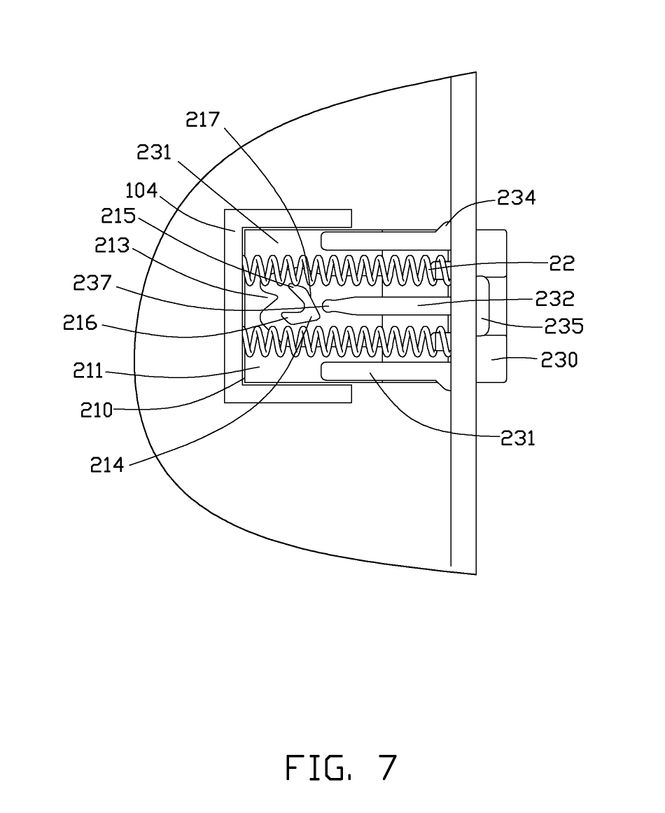

FIGS. 3 and 4 show the fastening block 21 has a wedge-shaped structure. The fastening block 21 defines an end wall 210. FIGS. 6 and 7, show that when the fastening block 21 is mounted in the mounting portion 104, the end wall 210 of the fastening block 21 contacts the inner surface of the mounting portion 104. The other end of the fastening block 21 is opposite to the end wall 210 and resists against the inner surface of the housing 10. Each elastic element 22 resists against the inner surface of the mounting portion 104 and the release element 23. An optional protrusion (not shown) may extend inward from the end wall 210 of the fastening block 21, and each elastic element 22 resists against the protrusion and the release element 23.

The release element 23 includes a pressing portion 230, and two guide columns 231, a stopper column 232, two fastening columns 233 respectively protruding from the inner surface of the pressing portion 230, and towards the fastening block 21. The two guide columns 231 are located at the two opposite sides of the pressing portion 230. The stopper column 232 is located near the center of the pressing portion 230. Each fastening column 233 is located between each guide column 231 and stopper column 232 (see FIG. 4).

Each guide column 231 further defines an wedge-shaped portion 234 at the junction of the guide column 231 and the pressing portion 230. The two wedge-shaped portions 234 may latch the inner portion of the end wall 101 against the housing 10 to prevent the release element 23 from completely popping out of the hole 102 under the elastic expansion of the elastic elements 22.

The pressing portion 230 has a shape and a size mating with the shape and size of the hole 102, so the pressing portion 230 can pass through the hole 102 and partially latch in the housing 10.

The fastening columns 233 are shorter than the guide columns 231 and the stopper column 232. Each fastening column 233 fastens around an end of each elastic element 22.

The fastening block 21 defines a sliding groove 212 on a surface 211 of the fastening block 21. A flange 213 pointing towards release element 23 is defined at one end of the sliding groove 212, and the other end of the sliding groove 212 defines an opening. A “V” shaped stopper portion 214 is defined on the sliding groove 212, adjacent to the flange 213. The stopper portion 214 includes two stopper arms 215, 216. The stopper arms 215, 216 respectively define a guide surface 217 (see FIG. 3). The longitudinal axis of the stopper portion 214 is angled from the stopper column 232 when the release element 23 is mounted in the mounting portion 104. That is, the stopper column 232 will resist against the guide surface 217 of the stopper arm 215 when the release element 23 is mounted in the mounting portion 104. The flange 213 includes a long side and a short side. The distal end of the stopper portion 214 and the distal end of the flange 213 deflect each other, and the distal end of the flange 213 is opposite to the stopper arm 215 of the stopper portion 214.

The flange 213 defines a first recessed portion having an arcuate closed end 218 and a second recessed portion having an arcuate closed end 219 at the two shoulders of the flange 213. The arcurate closed end 219 has a larger radius than the radius of the arcuate closed end 218. The first recessed portion having an arcuate closed end 218 is opposite to the inner end of the stopper arm 215. The second recessed portion having an arcuate closed end 219 is opposite to the outer end of the stopper arm 216 (see FIGS. 3 and 4).

The surface 211 of the fastening block 21 further defines an arcuate recessed section 220. The arcuate recessed section 220 has an arc mating with the arc of the pressing portion 230, allowing the pressing portion 230 to be partially received in the recessed section 220. A step is defined and connects the recessed section 220 and the sliding groove 212. The step can restrict the movement of the pressing portion 230 to the fastening block 21.

The pressing portion 230 defines a rope hole 235 for hanging ornaments. Two arcuate notches 236 are respectively defined at the two ends of the rope hole 235 for hanging the ornaments easily. The arcuate notches 236 can decorate the pressing portion 230.

The space between the out surfaces of the two guide columns 231 matches with the width of the mounting portion 104. When the pressing portion 230 is partially received in the recessed section 220 of the fastening block 21, the two guide columns 231 respectively contact the surface 211 at the regions adjacent to the sliding groove 212. While the pressing portion 230 is pressed to be completely received in the recessed section 220, or the pressing portion 230 partially pops out of the housing 10, the two guide columns 231 respectively slide on the surface 211 to guide the movement of the pressing portion 230.

The stopper column 232 defines a stopper pin 237 at the end of the stopper column 232. The stopper pin 237 vertically extends downward from the main body of the stopper column 232. The stopper column 232 and the stopper pin 237 are both made of resilient resins.

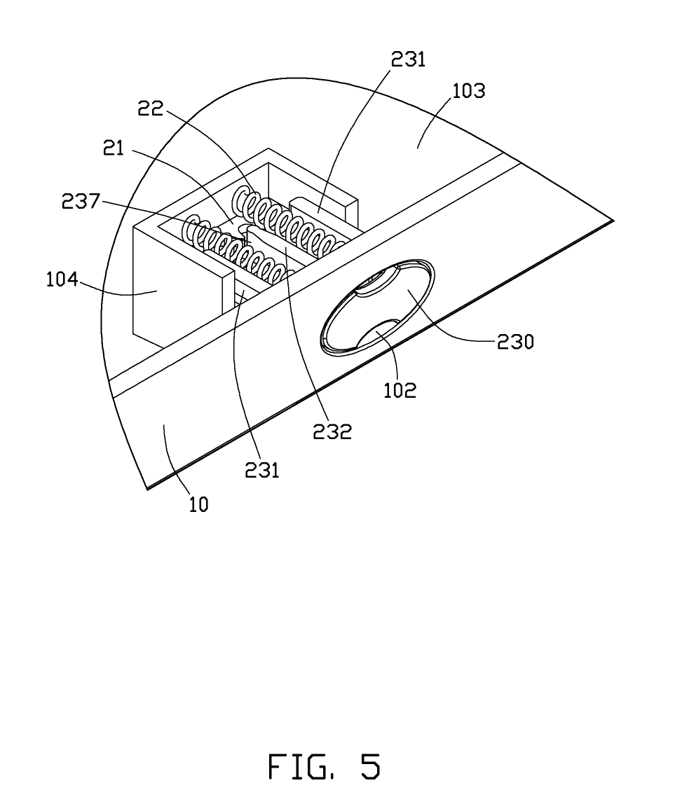

FIG. 5, shows assembly of the fastening assembly 20 to the housing 10, the fastening block 21 is secured in the mounting portion 104 first. The two elastic elements 22 are coiled on the two fastening columns 233 of the release element 23. Then the release element 23 is mounted to the mounting portion 104 through the hole 102, allowing the free ends of the two elastic elements 22 to resist against the mounting portion 104, and the stopper pin 237 of the stopper column 232 to latch in the stopper portion 214, thereby the release element 23 is completely received in the hole 102 with the out surface of the pressing portion 230 coplanar with the out surface of the end wall 101. The end of the pressing portion 230 adjacent to the wedge-shaped portions 234 is received in the recessed section 220. The two guide columns 231 contact the surface 211 at the regions adjacent to the sliding groove 212. The two elastic elements 22 are compressed.

FIGS. 6 and 7, show popping the release element 23 out of the housing 10, the pressing portion 230 is further pressed to compress the elastic elements 22, and the stopper pin 237 moves away from the stopper portion 214 to the flange 213. For the distal end of the flange 213 is deflected towards the stopper pin 237, the stopper pin 237 passes through the space between the flange 213 and the stopper arm 216 and urges to the second recessed portion having an arcuate closed end 219, thereby the stopper pin 237 moves around the end of the stopper arm 216 and arrives at the outer side of the stopper portion 214. When the pressing of the pressing portion 230 is released, the two elastic elements 22 are released to pop the pressing portion 230 out of the hole 102 of the housing 10.

FIG. 7, shows the pressing portion 230 popping out of the housing 10, the rope hole 235 being exposed, thereby users can quickly and conveniently fasten the ornaments to the fastening assembly 20 with the rope hole 235. The two wedge-shaped portions 234 respectively latch to the end wall 101, which prevents the pressing portion 230 completely popping out of the housing 10. The stopper pin 237 of the stopper column 232 arrives behind to the stopper portion 214 and is opposite to the guide surface 217 of the stopper arm 215.

After the ornaments are fastened to the fastening assembly 20, the pressing portion 230 of the release element 23 is pressed to the mounting portion 104. The two elastic elements 22 are gradually compressed. The stopper column 232 gradually moves to the stopper portion 214 and then contacts the guide surface 217 of the stopper arm 215. Since the stopper pin 237 and the stopper column 232 are resilient, the stopper pin 237 can further move along the guide surface 217 of the stopper arm 215 when the pressing portion 230 is further pressed and finally moves around the end of the stopper arm 215 and arrives at the first recessed portion having an arcuate closed end 218. When the pressing to the pressing portion 230 is released, the stopper pin 237 latches in the stopper portion 214, thereby the pressing portion 230 is completely mounted in the housing 10.

As discussed above, in the embodiment, ornaments can be conveniently and quickly fastened to the fastening assembly 20.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A fastening assembly, comprising:
a fastening block comprising a sliding groove and a stopper portion defined on the sliding groove;
a release element comprising a pressing portion defining a rope hole formed therein and a stopper column protruding from the pressing portion and towards the stopper portion, the end of the stopper column being releasably locked to the stopper portion; and
at least one elastic element resisting against the fastening block and the pressing portion;
when the pressing portion is pressed towards the fastening block, the end of the stopper column moving and getting around of the stopper portion, when the pressing of the pressing portion is released, the elastic element releases elastic expansion to push the pressing portion away from the fastening block.

2. The assembly as claimed in claim 1, wherein the fastening block has a surface, the sliding groove is defined in partial regions of the surface.

3. The assembly as claimed in claim 2, wherein a flange is defined at one end of the sliding groove, the other end of the sliding groove defines an opening, the flange defines an distal end, the stopper portion defines an another distal end, the distal end of the flange and the distal end of the stopper portion deflect each other.

4. The assembly as claimed in claim 3, wherein the flange defines a first recessed portion having an arcuate closed end and a second recessed portion having an arcuate closed end at the two sides of the distal end of the flange, the stopper portion comprises two stopper arms, the first recessed portion having an arcuate closed end is opposite to the inner end of one stopper arm, and the second recessed portion having an arcuate closed end is opposite to the outer end of the other stopper arm.

5. The assembly as claimed in claim 4, wherein the stopper column defines a stopper pin at the end of the stopper column, when the pressing portion is pressed towards the fastening block, the stopper pin moves and gets around one stopper arm to arrive at the first recessed portion having an arcuate closed end, when the pressing of the pressing portion is released, the stopper pin moves back to latch in the stopper portion.

6. The assembly as claimed in claim 5, wherein the stopper column and the stopper pin are both made of resilient resins.

7. The assembly as claimed in claim 4, wherein when the pressing portion is further pressed, the elastic element is further compressed, the stopper pin moves and gets around the other stopper arm of the stopper portion to arrive at the second recessed portion having an arcuate closed end, when the pressing of the pressing portion is released, the elastic element releases elastic expansion to pop the pressing portion out of the fastening block.

8. The assembly as claimed in claim 2, wherein the release element further comprises two guide columns and two fastening columns respectively protruded from the pressing portion and towards the fastening block, the two guide columns locate at the two opposite sides of the pressing portion, the stopper column locates at the centre of the pressing portion, and the fastening columns are respectively located between each guide column and the stopper column, the elastic element is coiled to the fastening column.

9. The assembly as claimed in claim 8, wherein the surface of the fastening block further defines an arcuate recessed section, the arcuate recessed section has an arc mating with the arc of the pressing portion, allowing the pressing portion to be partially received in the recessed section.

10. The assembly as claimed in claim 9, wherein a step is defined and connects the recessed section and the sliding groove, the step restricts the movement of the pressing portion to the fastening block.

11. The assembly as claimed in claim 9, wherein the two guide columns respectively contact and slide on the surface at the regions of adjacent to the sliding groove to guide the movement of the pressing portion.

12. The assembly as claimed in claim 1, wherein the pressing portion defines a rope hole therein.

13. An electronic device, comprising:
a housing having an inside bottom surface,
a mounting portion defined on the inside bottom surface and adjacent to an end of the housing; and
a fastening assembly mounted in the mounting portion;
the fastening assembly comprising:
a fastening block being received in the mounting portion of the housing, the fastening block comprising a sliding groove and a stopper portion defined on the sliding groove;
a release element comprising a pressing portion defining a rope hole formed therein and a stopper column protruding from the pressing portion and towards the stopper portion, the end of the stopper column being releasably locked to the stopper portion; and
at least one elastic element respectively resisting against the mounting portion and the pressing portion;
when the pressing portion being pressed towards the mounting portion, the end of the stopper column moving and getting around of the stopper portion, when the pressing of the pressing portion being released, the elastic element releasing elastic expansion to push the pressing portion away from the mounting portion of the housing.

14. The electronic device as claimed in claim 13, wherein the housing defines a hole in an end wall of the housing and opposite to the mounting portion, the pressing portion has a shape and a size mating with the shape and size of the hole, the pressing portion passes through the hole to be received in the housing, and/or the pressing portion is popped out of the housing via the hole.

15. The electronic device as claimed in claim 13, wherein the fastening block has a surface, the sliding groove is defined in partial regions of the surface, a flange is defined at one end of the sliding groove, and the other end of the sliding groove defines an opening, the flange defines an distal end, the stopper portion defines an another distal end, the distal end of the flange and the distal end of the stopper portion deflect each other.

16. The electronic device as claimed in claim 15, wherein the flange defines a first recessed portion having an arcuate closed end and a second recessed portion having an arcuate closed end at the two sides of the distal end, the stopper portion comprises two stopper arms, the first recessed portion having an arcuate closed end is opposite to the inner end of one stopper arm, and the second recessed portion having an arcuate closed end is opposite to the outer end of the other stopper arm.

17. The electronic device as claimed in claim 16, wherein the stopper column defines a stopper pin at the end of the stopper column, when the pressing portion is pressed towards the mounting portion, the stopper pin moves and gets around one stopper arm to arrive at the first recessed portion having an arcuate closed end, when the pressing of the pressing portion is released, the stopper pin moves back to latch in the stopper portion.

18. The electronic device as claimed in claim 17, wherein when the pressing portion is further pressed, the elastic element is further compressed, the stopper pin moves and get around the other stopper arm of the stopper portion to arrive at the second recessed portion having an arcuate closed end, when the pressing of the pressing portion is released, the elastic element releases elastic expansion to pop the pressing portion out of the hole of the housing.

19. The electronic device as claimed in claim 15, wherein the release element further comprises two guide columns and two fastening columns respectively protruded from the pressing portion and towards the mounting portion of the housing, the two guide columns locate at the two opposite sides of the pressing portion, the stopper column locates at the centre of the pressing portion, and the fastening columns are respectively located between each guide column and the stopper column, the elastic element is coiled to the fastening column, the two guide columns respectively contact and slide on the surface of the fastening block at the regions of adjacent to the sliding groove to guide the movement of the pressing portion.

20. The electronic device as claimed in claim 19, wherein each guide column defines an wedge-shaped portion on the junction of the guide column and the pressing portion, the wedge-shaped portion latch the inner surface of the end wall of the housing to prevent the release element completely popping out of the hole of the housing.
